(19) United States
(12) Patent Application Publication
(10) Pub. No.: US 2025/0210445 A1
(43) Pub. Date: Jun. 26, 2025

(54) HEAT DISSIPATION MEMBER AND SEMICONDUCTOR MODULE

(71) Applicant: NIDEC CORPORATION, Kyoto (JP)

(72) Inventors: Yuki YANAGITA, Kyoto (JP); Koji MURAKAMI, Kyoto (JP)

(21) Appl. No.: 18/848,129

(22) PCT Filed: Mar. 7, 2023
(86) PCT No.: PCT/JP2023/008577

§ 371 Date: Sep. 18, 2024

(30) Foreign Application Priority Data
Mar. 24, 2022 (JP) 2022-048866

(51) Int. Cl. H01L 23/367; H01L 23/34

(52) U.S. Cl. CPC H01L 23/3672; H01L 23/345

(57) ABSTRACT

A heat dissipation member includes a plate-shaped base portion that extends in a first direction along a direction in which a refrigerant flows and in a second direction orthogonal to the first direction and has thickness in a third direction orthogonal to the first direction and the second direction, and a fin projecting from the base portion toward one side in the third direction. The fin includes a flat plate-shaped side wall portion that extends in the first direction and the third direction, and has a thickness direction in the second direction. The side wall portion has a slit penetrating in the second direction. The number of the slits for each of regions defined by the same length in the first direction increases toward one side in the first direction which is the downstream side.

### TECHNICAL FIELD

The present disclosure relates to a heat dissipation member.

### BACKGROUND ART

Conventionally, a cooling device including a water jacket used for water cooling and a heat dissipation member is known. The heat dissipation member includes a fin for cooling. A fin is accommodated in the water jacket. The inside of the water jacket serves as a flow path of cooling water, and a heating element is cooled via the fin (see, for example, Patent Literature 1).

### CITATIONS LIST

### Patent Literature

Patent Literature 1: JP 2017-108068 A

### SUMMARY OF INVENTION

### Technical Problems

Here, the cooling device is required to have improved cooling performance and to have a reduced pressure loss. This is because when a pressure loss is large, a desired flow rate cannot be secured depending on performance of a pump, or it is necessary to employ a large and high power consumption pump in order to secure a desired flow rate.

In view of the above circumstances, an object of the present disclosure is to provide a heat dissipation member capable of improving cooling performance and reducing a pressure loss.

### Solutions to Problems

An exemplary heat dissipation member according to the present disclosure includes a plate-shaped base portion that extends in a first direction along a direction in which a refrigerant flows and in a second direction orthogonal to the first direction and has thickness in a third direction orthogonal to the first direction and the second direction, and a fin projecting from the base portion toward one side in the third direction. The fin includes a flat plate-shaped side wall portion that extends in the first direction and the third direction, and has a thickness direction in the second direction. The side wall portion has a slit penetrating in the second direction. The number of the slits for each of regions defined by the same length in the first direction increases toward one side in the first direction which is the downstream side.

### Advantageous Effects of Invention

According to the exemplary heat dissipation member of the present disclosure, cooling performance can be improved, and a pressure loss can be reduced.

### BRIEF DESCRIPTION OF DRAWINGS

FIG. 1 is a perspective view of a heat dissipation member according to a first embodiment of the present disclosure.

FIG. 2 is a side cross-sectional view of the heat dissipation member according to the first embodiment of the present disclosure.

FIG. 3 is a perspective view of the heat dissipation member according to a second embodiment of the present disclosure.

FIG. 4 is a side cross-sectional view of the heat dissipation member according to the second embodiment of the present disclosure.

FIG. 5 is a perspective view of a fin according to the second embodiment of the present disclosure.

### DESCRIPTION OF EMBODIMENTS

Hereinafter, an exemplary embodiment of the present disclosure will be described with reference to the drawings.

Note that, in the drawings, with a first direction as an X direction, X1 indicates one side in the first direction, and X2 indicates another side in the first direction. The first direction is a direction along a direction F in which a refrigerant W flows, and the downstream side is indicated by F1 and the upstream side is indicated by F2. The downstream side F1 is one side in the first direction, and the upstream side F2 is another side in the first direction. Further, with a second direction orthogonal to the first direction as a Y direction, Y1 indicates one side in the second direction, and Y2 indicates another side in the second direction. Further, with a third direction orthogonal to the first direction and the second direction as a Z direction, Z1 indicates one side in the third direction, and Z2 indicates another side in the third direction. Note that the above-described “orthogonal” also includes intersection at an angle slightly shifted from 90°. Further, each of the above-described directions does not limit a direction when a heat dissipation member 5 is incorporated in various devices.

### 1. First Embodiment

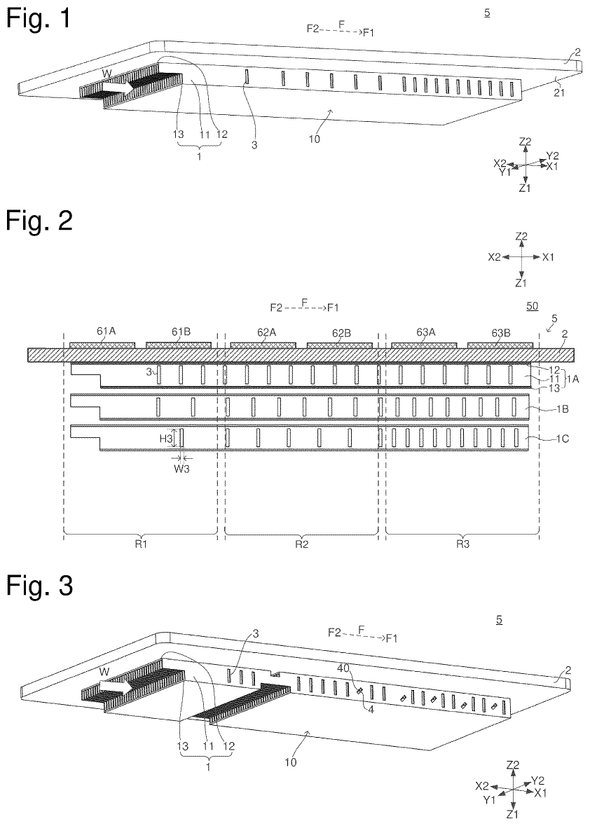

FIG. 1 is a perspective view of the heat dissipation member 5 according to a first embodiment of the present disclosure. FIG. 2 is a side cross-sectional view of the heat dissipation member 5. FIG. 2 is a diagram illustrating a state in which the heat dissipation member 5 is cut along a cut surface orthogonal to the second direction at a halfway position in the second direction as viewed toward one side in the second direction. Note that, in FIG. 2, a fin illustrated as a fin 1C is a fin 1 corresponding to FIG. 1, and fins 1A and 1B illustrate a configuration of the fin 1 for comparison. Comparison of the fins 1A, 1B, and 1C will be described later.

A cooling device includes the heat dissipation member 5 and a liquid cooling jacket (not illustrated) in which the heat dissipation member 5 is installed. The cooling device is a device for cooling a plurality of semiconductor devices 61A, 61B, 62A, 62B, 63A, and 63B (hereinafter, 61A and the like) (see FIG. 2). The semiconductor device is an example of a heating element. The semiconductor devices 61A and the like are a power transistor of an inverter included in a traction motor for driving a wheel of a vehicle, for example. The power transistor is, for example, an insulated gate bipolar transistor (IGBT). In this case, the cooling device is mounted on the traction motor. Note that the number of semiconductor devices may be plural other than six or may be one.

The heat dissipation member 5 includes a base portion 2 and a heat dissipation fin portion 10. The base portion 2 has a plate shape that extends in the first direction and the second direction and has thickness in the third direction. The base portion 2 is made from metal having high thermal conductivity, such as a copper alloy.

The heat dissipation fin portion 10 is fixed to one side in the third direction of the base portion 2. The heat dissipation fin portion 10 is configured as what is called a stacked fin formed by arranging, in the second direction, a plurality of the fins 1 formed of one metal plate extending in the first direction. The fin 1 is made from, for example, a copper plate.

The fin 1 includes a side wall portion 11, a bottom plate portion 12, and a top plate portion 13. The side wall portion 11 has a flat plate shape extending in the first direction and the third direction with the second direction being a thickness direction.

The bottom plate portion 12 is bent toward one side in the second direction at an end portion on another side in the third direction of the side wall portion 11. The top plate portion 13 is bent toward one side in the second direction at an end portion on one side in the third direction of the side wall portion 11. Accordingly, a cross-section of the fin 1 has a rectangular U-shape. The heat dissipation fin portion 10 having the fins 1 stacked in the second direction is fixed to the base portion 2 by fixing the bottom plate portion 12 to a side surface 21 on one side in the third direction of the base portion 2 by, for example, brazing. That is, the heat dissipation member 5 has the fin 1 projecting from the base portion 2 toward one side in the third direction.

As illustrated in FIG. 1, the refrigerant W flows into the heat dissipation fin portion 10 from another side (upstream side) in the first direction. The refrigerant W is, for example, water or an ethylene glycol aqueous solution. The refrigerant W flows to one side in the first direction inside a flow path formed between the fins 1 adjacent to each other in the second direction, and is discharged from the heat dissipation fin portion 10 to the outside. The semiconductor devices 61A and the like are arranged on another side in the third direction of the base portion 2 (see FIG. 2). Heat generated from the semiconductor devices 61A and the like moves to the refrigerant W through the base portion 2 and the fin 1, so that the semiconductor devices 61A and the like are cooled. Note that a semiconductor module 50 includes the heat dissipation member 5 and the semiconductor devices 61A and the like as a heating element arranged on another side in the third direction of the base portion 2 (see FIG. 2).

The side wall portion 11 of the fin 1 is provided with a plurality of slits 3 arranged side by side in the first direction. The slit 3 is an opening penetrating in the second direction. That is, the side wall portion 11 has the slit 3 penetrating in the second direction.

In the configuration illustrated in FIGS. 1 and 2, seventeen of the slits 3 are provided as an example. As illustrated in FIG. 2, regions R1, R2, and R3 are arranged in the first direction. Lengths in the first direction of the regions R1, R2, and R3 are equal. The region R1 includes the semiconductor devices 61A and 61B. The region R2 includes the semiconductor devices 62A and 62B. The region R3 includes the semiconductor devices 63A and 63B.

As illustrated in FIG. 2, in a case of the fin 1A, three of the slits 3 are provided in the region R1, eight of the slits 3 are provided in the region R2, and six of the slits 3 are provided in the region R3. In a case of the fin 1B, two of the slits 3 are provided in the region R1, six of the slits 3 are provided in the region R2, and eight of the slits 3 are provided in the region R3. In a case of the fin 1C (corresponding to FIG. 1), one of the slit 3 is provided in the region R1, five of the slits 3 are provided in the region R2, and ten of the slits 3 are provided in the region R3.

Provision of the slit 3 destroys a temperature boundary layer of flow developing on the side wall portion 11 of the fin 1 and promotes turbulence, but leads to an increase in a pressure loss. However, in the fins 1B and 1C, as described above, the number of the slits 3 for each of the regions R1, R2, and R3 defined in the same length in the first direction increases toward one side in the first direction which is the downstream side. Temperature of the refrigerant W is higher on the downstream side than on the upstream side, and temperature of a heating element tends to be higher on the downstream side than on the upstream side. Accordingly, as described above, by increasing installation density of the slits 3 toward the downstream side, it is possible to reduce a temperature difference in the semiconductor devices 61A and the like (heating element) while reducing increase in a pressure loss. Note that, in the fin 1C having a largest number of the slits 3 installed in the region R3 furthest on the downstream side among the fins 1A, 1B, and 1C, maximum temperature of the semiconductor devices 61A and the like is lowest.

Further, as illustrated in FIG. 2, at least one of the heating elements 61A and the like can be installed on another side in the third direction of the base portion 2, and heating units (61A, 61B) (62A, 62B) (63A, 63B) included in the heating element can be installed for each of the regions R1, R2, and R3 on another side in the third direction of the base portion 2. By the above, it is possible to reduce a temperature difference in a heating unit installed for each of the regions R1, R2, and R3.

Note that, in a case where one heating element extending in the first direction over the regions R1, R2, and R3 is provided in the base portion 2, each heating unit included in the heating element is arranged in each of the regions R1, R2, and R3, and a temperature difference between the heating units can be reduced. Further, regions defined by the same length in the first direction are not limited to being defined depending on arrangement of a semiconductor device (heating element) as illustrated in FIG. 2.

Further, as illustrated in FIG. 2, in the fins 1B and 1C, the number of the slits 3 is largest in the region R3 with respect to the heating unit (63A, 63B) installed furthest on one side in the first direction among the heating units (61A, 61B) (62A, 62B) (63A, 63B) that can be installed. Since temperature of the refrigerant W increases, temperature of the heating unit (63A, 63B) furthest on the downstream side becomes highest temperature of the heating units. However, by making the number of the slits 3 in the region R3 with respect to the heating unit largest, the highest temperature of the heating units can be lowered.

Further, as illustrated in FIG. 2, height H3 in the third direction of the slit 3 is longer than width W3 in the first direction of the slit 3. By the above, it is possible to prevent lowering in cooling performance due to decrease in a surface area of the fin 1 by provision of the slit 3.

### 2. Second Embodiment

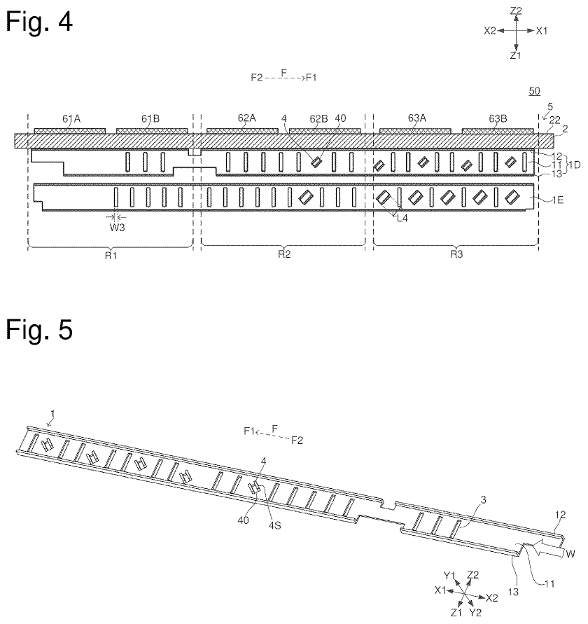

FIG. 3 is a perspective view of the heat dissipation member 5 according to a second embodiment of the present disclosure. FIG. 4 is a side cross-sectional view of the heat dissipation member 5 according to the second embodiment. Note that, in FIG. 4, a fin illustrated as a fin 1D is the fin 1 corresponding to FIG. 3, and a fin 1E illustrates a configuration of the fin 1 for comparison. Comparison between the fins 1D and 1E will be described later.

In the second embodiment, a spoiler 4 is provided in addition to the slit 3 in the fin 1. The spoiler 4 will be described in detail with reference to FIG. 5. FIG. 5 is a perspective view of the fin 1.

As illustrated in FIG. 5, the side wall portion 11 of the fin 1 is provided with the spoiler 4 in addition to the slit 3. The side wall portion 11 is provided with a through hole 40 penetrating in the second direction. The through hole 40 has a rectangular shape. The through hole 40 has a pair of facing sides facing each other inclined on one side in the first direction and another side in the third direction. The spoiler 4 is formed by being bent to one side in the second direction on the facing side. The through hole 40 and the spoiler 4 can be formed by cutting and bending the side wall portion 11. Note that the configuration may be such that the spoiler is provided only on one of the facing sides in one of the through hole 40. As described above, the fin 1 has the spoiler 4 projecting in the second direction from the side wall portion 11.

The spoiler 4 has a facing surface 4S facing a direction in which the refrigerant W flows, that is, one side in the first direction. The spoiler 4 has a function of interrupting flow of the refrigerant W by the facing surface 4S. Turbulent flow of the refrigerant W is easily generated in the vicinity of the facing surface 4S, and cooling performance of the fin 1 can be improved. Further, the spoiler 4 is inclined to one side in the first direction and another side in the third direction. By the above, the refrigerant W can be guided to the base portion 2 side (another side in the third direction) by the spoiler 4, and cooling performance can be improved.

In the slit 3, it is difficult to stir the refrigerant W close to a heating element (semiconductor devices 61A and the like) mounting surface 22 (see FIG. 4) and the refrigerant W away from the heating element mounting surface 22. However, with the spoiler 4, it is easy to stir the refrigerant W in the third direction. Temperature of the refrigerant W closer to the heating element mounting surface 22 increases toward the downstream side, and a temperature difference from the refrigerant W away from the heating element mounting surface 22 is generated. However, by stirring the refrigerant W in the third direction by the spoiler 4, temperature of the refrigerant W closer to the heating element mounting surface 22 can be lowered. Therefore, an effect of improving cooling performance of the spoiler 4 with respect to the slit 3 is larger toward the downstream side.

In view of the above, in the present embodiment, in the fin 1D (corresponding to FIG. 3) illustrated in FIG. 4, the number of the spoilers 4 is zero with respect to three of the slits 3 in the region R1, the number of the spoilers 4 is one with respect to seven of the slits 3 in the region R2, and the number of the spoilers 4 is four with respect to seven of the slits 3 in the region R3. Note that, here, the number of the spoilers 4 is the number of sets of the spoilers 4. Further, the regions R1, R2, and R3 are regions defined by the same length in the first direction as in the first embodiment.

That is, a ratio of the number of the spoilers 4 to the number of the slits 3 in each of the regions R1, R2, and R3 increases toward one side in the first direction. By the above, by stirring the refrigerant W in the third direction by the spoiler 4 furthest on downstream side where temperature of the refrigerant W close to the heating element mounting surface 22 is high, temperature of a heating element (the semiconductor devices 63A and 63B) furthest on the downstream side can be lowered as compared with a case where only the slit 3 is provided. Further, the spoiler 4 greatly changes a direction of flow of the refrigerant W as compared with the slit 3, which causes increase in a pressure loss. However, since the number of the spoilers 4 is small on the upstream side, increase in a pressure loss can be reduced as a whole.

Note that, also in the fin 1E illustrated in FIG. 4, the number of the spoilers 4 is zero with respect to five of the slits 3 in the region R1, the number of the spoilers 4 is one with respect to nine of the slits 3 in the region R2, and the number of the spoilers 4 is four with respect to four of the slits 3 in the region R3, and a ratio of the number of the spoilers 4 with respect to the number of the slits 3 increases toward one side in the first direction.

Further, in the present embodiment, the width W3 in the first direction of the slit 3 (see FIG. 4) is larger than thickness of the side wall portion 11 to prevent clogging by contamination and to facilitate processing. In this case, in a case where only the slit 3 is provided in the side wall portion 11, if the number of the slits 3 is increased furthest on the downstream side, a surface area of the fin 1 decreases, and cooling performance is limited. On the other hand, in a case of the slit 3 having the size as described above, it is possible to improve cooling performance furthest on the downstream side by providing the spoiler 4 in addition to the slit 3.

Further, as illustrated in FIG. 4, in the fin 1D, the number of the slits 3 is seven and the number of the spoilers 4 is four in the region R3 furthest on the downstream side. That is, in the region R3 furthest on one side in the first direction, the number of the slits 3 is larger than the number of the spoilers 4. The fin 1D is designed with emphasis on an effect of reducing a pressure loss rather than an effect of lowering temperature of a heating element.

Further, as illustrated in FIG. 4, in the fin 1E, the number of the slits 3 is four and the number of the spoilers 4 is five in the region R3 furthest on the downstream side. That is, in the region R3 furthest on one side in the first direction, the number of the spoilers 4 is larger than the number of the slits 3. The fin 1E is designed with emphasis on an effect of lowering temperature of a heating element rather than an effect of reducing a pressure loss.

Note that, in the fin 1E, a length L4 along the facing side of the spoiler 4 is made longer than that of the fin 1D. By the above, cooling performance is more emphasized in the design.

### 3. Others

The embodiment of the present disclosure is described above. Note that the scope of the present disclosure is not limited to the above embodiment. The present disclosure can be implemented by making various changes to the above embodiment without departing from the gist of the invention. Further, the matters described in the above embodiment can be optionally combined together, as appropriate, as long as there is no inconsistency.

The present disclosure can be used for cooling various heating elements.

### REFERENCE SIGNS LIST

1 fin
1A, 1B, 1C fin
1D, 1E fin
2 base portion
3 slit
4 spoiler
4S facing surface
5 heat dissipation member
10 heat dissipation fin portion
11 side wall portion
12 bottom plate portion
13 top plate portion
21 surface on one side in third direction
22 heating element mounting surface
40 through hole
50 semiconductor module
61A, 61B, 62A, 62B, 63A, 63B semiconductor device
R1, R2, R3 region
N refrigerant

1. A heat dissipation member comprising:
a plate-shaped base portion that extends in a first direction along a direction in which a refrigerant flows and in a second direction orthogonal to the first direction, and has thickness in a third direction orthogonal to the first direction and the second direction; and
a fin that projects from the base portion to one side in the third direction, wherein
the fin includes a flat plate-shaped side wall portion that extends in the first direction and the third direction and has a thickness direction in the second direction,
the side wall portion has a slit penetrating in the second direction, and
a number of the slits for each of regions defined by a same length in the first direction increases toward one side in the first direction which is a downstream side.

2. The heat dissipation member according to claim 1, wherein
at least one heating element can be installed on another side in the third direction of the base portion, and
a heating unit included in the heating element is installable for each of the regions on another side in the third direction of the base portion.

3. The heat dissipation member according to claim 2, wherein
a number of the slits in the region with respect to the heating unit installed furthest on one side in the first direction among the heating units that can be installed is largest.

4. The heat dissipation member claim 1, wherein
height in the third direction of the slit is longer than width in the first direction of the slit.

5. The heat dissipation member according to claim 1, wherein
the fin includes a spoiler projecting in the second direction from the side wall portion, and
a ratio of a number of the spoilers to a number of the slits in each of the regions increases toward one side in the first direction.

6. The heat dissipation member according to claim 5, wherein
width in the first direction of the slit is larger than thickness of the side wall portion.

7. The heat dissipation member according to claim 5, wherein
a number of the slits is larger than a number of the spoilers in the region furthest on one side in the first direction.

8. The heat dissipation member according to claim 5, wherein
a number of the spoilers is larger than a number of the slits in the region furthest on one side in the first direction.

9. A semiconductor module comprising:
the heat dissipation member according to claim 1; and
a semiconductor device as a heating element arranged on another side in the third direction of the base portion.
